(19) United States
(12) Patent Application Publication
(10) Pub. No.: US 2003/0038371 A1
(43) Pub. Date: Feb. 27, 2003

(54) METHOD OF FORMING A METALLIC INTERCONNECT STRUCTURE WITH A METALLIC SPACER

(76) Inventors: Chen-Chiu Hsue, Hsinchu (TW); Cheng-Hui Chung, Hsinchu Hsien (TW); Yei-Hsiung Lin, Hsinchu (TW)

Correspondence Address: BIRCH STEWART KOLASCH & BIRCH, PO BOX 747, FALLS CHURCH, VA, 22040-0747, US

(21) Appl. No.: 09/933,947

(22) Filed: Aug. 22, 2001

(51) Int. Cl. H01L 23/52

(52) U.S. Cl. 257/762

(57) ABSTRACT

A metallic interconnect structure has at least a metallic interconnects patterned on a semiconductor substrate, and at least a metallic spacer formed on the sidewall of the metallic interconnect. The metallic interconnect is Al, Cu or Al—Si—Cu. The first metallic layer is Ti, TiN, Ta, or TaN.

### BACKGROUND OF THE INVENTION

1. Field of the Invention

The present invention relates to a metallic interconnect process and, more particularly, to a metallic interconnect structure with a metallic spacer and a method of forming the metallic interconnect structure.

2. Description of the Related Art

In conventional metallic interconnect process, a silicon oxide layer sandwiched between metallic interconnects serves as an inter-metal dielectric (IMD) layer. However, when using photolithography and etching to pattern the metallic interconnect, the probability of resulting a misalignment phenomenon increases as the size of the integration circuits is reduced. Also, the misalignment phenomenon leads to over etch the underlain IMD layer, thus brings about leakage current and decreases product reliability. In addition, the width of the metallic interconnect narrowed down as the size of the integration circuits is reduced, thereby the metallic interconnect may collapse to decrease the yield.

U.S. Pat. No. 5,580,701 provides a method of decreasing the standing wave effect on a photoresist layer in which an anti-reflective coating (ARC) of silicon dioxide, silicon nitride or silicon-oxy-nitride is formed on a metallic layer. But this still cannot solve the above-mentioned problems.

FIGS. 1a to 1c are schematic cross-sectional diagrams showing conventional metallic interconnect process. As shown in FIG. 1a, a semiconductor substrate 100 has a plurality of metallic interconnects 110, 120 patterned on the substrate 100, and a silicon dioxide layer 130 formed on the exposed region of the metallic interconnects 110, 120 and the substrate 100. Next, as shown in FIG. 1b, using photolithography, etching and depositing, aplug 140 is formed in a via to pass through the silicon dioxide layer 130 and electrically connect to the metallic interconnect 110. If the misalignment phenomenon occurs in photolithography and etching, the silicon dioxide layer 130 is over etched and thus causes the plug 140 to be much close to the substrate 100. This may break the silicon dioxide layer 130, resulting in leakage current. In addition, as shown in FIG. 1c, when the metallic interconnects 110, 120 are narrowed, the metallic interconnects 110, 120 may collapse to become the undesired shape 150, 160.

Thus, a novel metallic interconnect structure to solve the aforementioned problems is called for.

### SUMMARY OF THE INVENTION

The present invention provides a metallic interconnect structure which has at least a metallic interconnects patterned on a semiconductor substrate, and at least a metallic spacer formed on the sidewall of the metallic interconnect. The metallic interconnect is Al, Cu or Al—Si—Cu. The first metallic layer is Ti, TiN, Ta, or TaN.

The present invention provides a method of forming the metallic interconnect structure. First, a semiconductor substrate is provides with a plurality of metallic interconnects. Then, a first metallic layer is formed on the exposed surface of the substrate and the metallic interconnects. Next, using etching back on the first metallic layer, the tops of the metallic interconnects and the surface of the substrate are exposed, thus the remaining part of the first metallic layer on the sidewall of the metallic interconnects serves as a first metallic spacer. Next, a dielectric layer is formed to cover the exposed surface of the substrate, the metallic interconnects and the first metallic spacer. Finally, a planarization technique is used on the dielectric layer to provide a planar surface. In addition, before forming the dielectric layer, a second metallic spacer can be formed on the first metallic spacer. Therefore, dual metallic spacers are formed on the sidewall each of the metallic interconnects.

Accordingly, it is a principal object of the invention to provide a metallic interconnect structure with a metallic spacer.

It is another object of the invention to provide a metallic interconnect structure with dual metallic spacers.

Yet another object of the invention is to provide the metallic spacer as an etch-stop layer to solve the problems caused by misalignment phenomenon.

It is a further object of the invention to increase product reliability.

Still another object of the invention is to provide the metallic spacer as a buffering layer to increase adhesion

These and other objects of the present invention will become readily apparent upon further review of the following specification and drawings.

### BRIEF DESCRIPTION OF THE DRAWINGS

FIGS. 1a to 1c are schematic cross-sectional diagrams showing conventional metallic interconnect process.

FIGS. 2˜7 are schematic cross-sectional diagrams showing a method of forming a metallic interconnect structure according to the first embodiment of the present invention.

FIG. 8 is schematic cross-sectional diagrams showing a metallic interconnect structure according to the first embodiment of the present invention.

FIGS. 9˜16 are schematic cross-sectional diagrams showing a method of forming a metallic interconnect structure according to the second embodiment of the present invention.

FIG. 17 is schematic cross-sectional diagrams showing a metallic interconnect structure according to the second embodiment of the present invention.

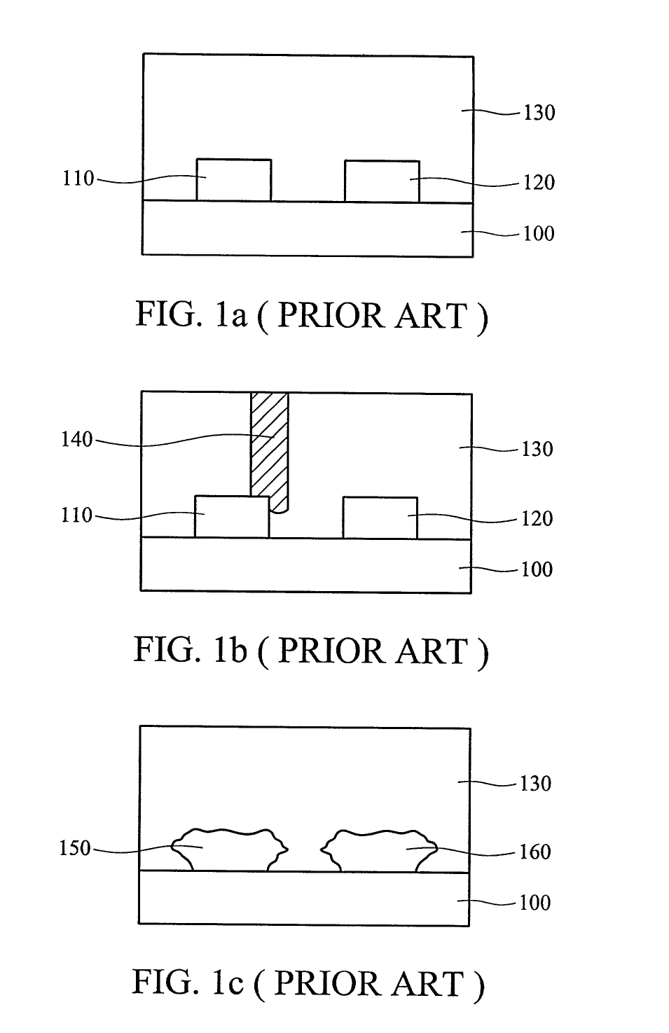

Similar reference characters denote corresponding features consistently throughout the attached drawings.

### DETAILED DESCRIPTION OF THE PREFERRED EMBODIMENTS

First Embodiment

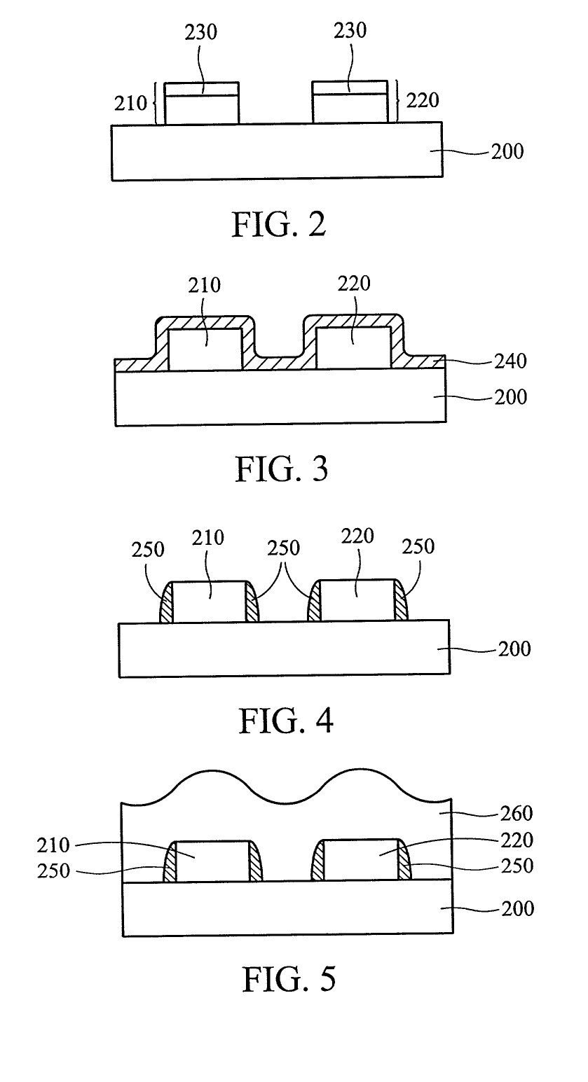

FIGS. 2˜7 are schematic cross-sectional diagrams showing a method of forming a metallic interconnect structure according to the first embodiment of the present invention. As shown in FIG. 2, a semiconductor substrate 200 has a plurality of metallic interconnects 210, 220 patterned on the substrate 200, and an anti-reflective coating (ARC) 230 formed on the tops of the metallic interconnects 210, 220. Preferably, the metallic interconnects 210, 220 is of aluminum (Al), copper (Cu) or Al—Si—Cu and formed by chemical vapor deposition (CVD). The ARC 230 may be a single layer, such as a SiON layer or a multiple layers, such as a Ti/TiN structure.

As shown in FIG. 3, a first metallic layer 240 of 50˜300 Å thickness is conformally deposited on the exposed surface of the substrate 200 and the metallic interconnects 210, 220. Preferably, the first metallic layer 240 is of Ti, TiN, Ta, TaN or other metallic materials and formed by magnetic DC sputtering. Then, as shown in FIG. 4, using dry etching with a combination of BCl₃/Cl₂ as reactive gases, the first metallic layer 240 on the top of the metallic interconnects 210, 220 and the exposed substrate 200 is removed. Thus, the remaining part of the first metallic layer 240 on the sidewall of the metallic interconnects 210, 220 serves as a metallic spacer 250.

As shown in FIG. 5, using CVD, a dielectric layer 260 of silicon dioxide is overall deposited on the exposed surface of the substrate 200. Next, as shown in FIG. 6, using planarization treatment, such as etching back process or chemical mechanical polishing (CMP) method, the dielectric layer 260′ is formed with a planar surface.

As shown in FIG. 7, using photolithography, etching and depositing, a plug 280 of tungsten (W) is formed to pass through the dielectric layer 260′ and electrically connect to the metallic interconnect 210. If a misalignment phenomenon occurs during photolithography, the metallic spacer 250 serves as an etch-stop layer and thereby a part of plug 280 can be formed on the metallic spacer 250. This prevents a leakage current problem caused by over etching the dielectric layer 260′ so as to increase product reliability. Also, this increases the tolerance of the misalignment phenomenon during photolithography, thus the design rule of the integration circuits can be applied to a smaller unit.

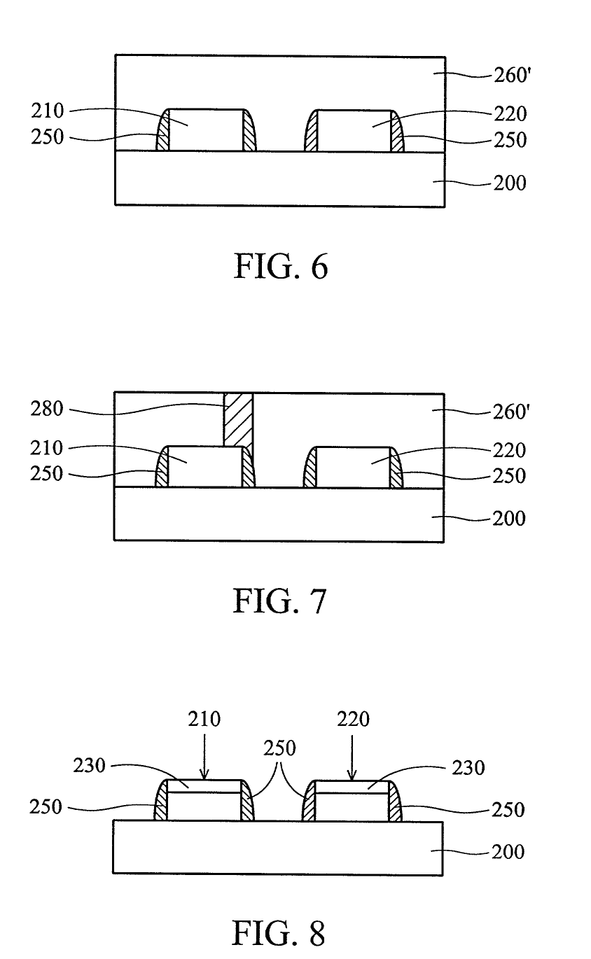

According to the above-mentioned method, a structure of metallic interconnect is provided to solve problems caused by the misalignment phenomenon. FIG. 8 is schematic cross-sectional diagrams showing a metallic interconnect structure according to the first embodiment of the present invention. The metallic interconnect structure comprises the metallic interconnects 210, 220, and the metallic spacer 250 formed on the sidewall of the metallic interconnects 210, 220.

Second Embodiment

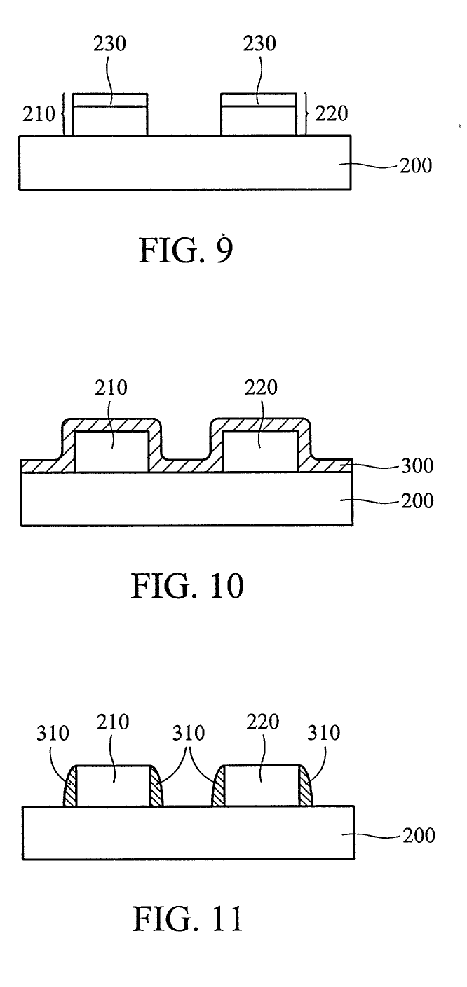

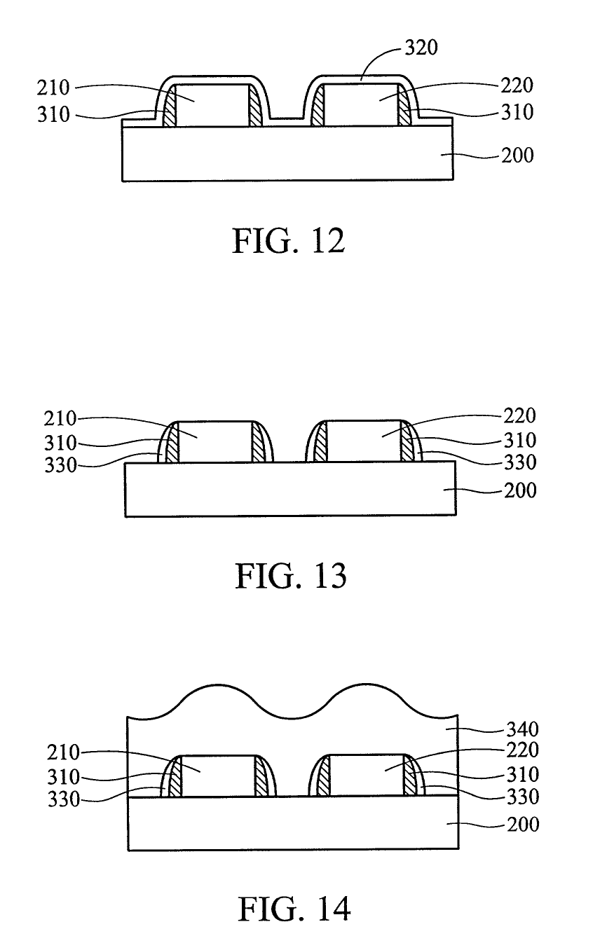

FIGS. 9˜16 are schematic cross-sectional diagrams showing a method of forming a metallic interconnect structure according to the second embodiment of the present invention. As shown in FIG. 9, the semiconductor substrate 200 has metallic interconnects 210, 220 patterned on the substrate 200, and the anti-reflective coating (ARC) 230 formed on the tops of the metallic interconnects 210, 220. Preferably, the metallic interconnects 210, 220 is of aluminum (Al), copper (Cu) or Al—Si—Cu and formed by chemical vapor deposition (CVD) The ARC 230 may be a single layer, such as a SiON layer or a multiple layers, such as a Ti/TiN structure.

As shown in FIG. 10, a first metallic layer 300 of 50˜300 Å thickness is conformally deposited on the exposed surface of the substrate 200 and the metallic interconnects 210, 220. Preferably, the first metalliclayer 300 is of Ti, Ta, or other metallic materials and formed by magnetic DC sputtering. Then, as shown in FIG. 11, using dry etching with a combination of BCl₃/Cl₂ as reactive gases, the first metallic layer 300 on the top of the metallic interconnects 210, 220 and the exposed substrate 200 is removed. Thus, the remaining part of the first metallic layer 300 on the sidewall of the metallic interconnects 210, 220 serves as a first metallic spacer 310.

As shown in FIG. 12, a second metallic layer 320 of 50˜300 Å thickness is conformally deposited on the exposed surface of the substrate 200 to cover the first metallic spacer 310. Preferably, the second metallic layer 320 is of TiN, TaN, or other metallic alloys and formed by magnetic DC sputtering. Then, as shown in FIG. 13, using dry etching with a combination of BCl₃/Cl₂ as reactive gases, the second metallic layer 320 on the top of the metallic interconnects 210, 220 and the exposed substrate 200 is removed. Thus, the remaining part of the second metallic layer 320 on the sidewall of the first metallic spacer 310 serves as a second metallic spacer 330.

As shown in FIG. 14, using CVD, a dielectric layer 340 of silicon dioxide is overall deposited on the exposed surface of the substrate 200. Next, as shown in FIG. 15, using planarization treatment, such as etching back process or chemical mechanical polishing (CMP) method, the dielectric layer 340′ is formed with a planar surface.

As shown in FIG. 16, using photolithography, etching and depositing, a plug 350 of tungsten (W) is formed to pass through the dielectric layer 340′ and electrically connect to the metallic interconnect 210. If a misalignment phenomenon occurs during photolithography, the second metallic spacer 330 serves as an etch-stop layer and thereby a part of plug 350 can be formed on the second spacer 330. This prevents a leakage current problem caused by over etching the dielectric layer 340′ so as to increase product reliability. Also, this increases the tolerance of the misalignment phenomenon during photolithography, thus the design rule of the integration circuits can be applied to a smaller unit. In addition, the first metallic spacer 310 serves as a buffering layer to increase the adhesion of the metallic interconnects 210, 220 and the second metallic spacer 330. This prevents cracks or other defects and further increases the product reliability.

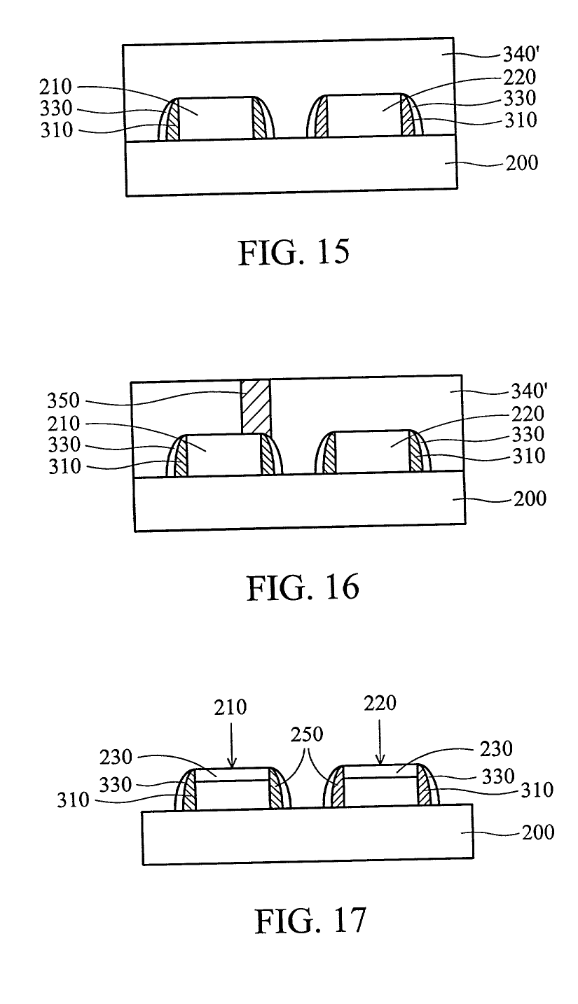

According to the above-mentioned method, a structure of metallic interconnect with dual metallic spacer is provided to solve problems caused by the misalignment phenomenon. FIG. 17 is schematic cross-sectional diagrams showing a metallic interconnect structure according to the second embodiment of the present invention. The metallic interconnect structure comprises the metallic interconnects 210, 220, a first metallic spacer 310 formed on the sidewall of the metallic interconnects 210, 220, and a second metallic spacer 330 formed on the first metallic spacer 310.

It is to be understood that the present invention is not limited to the embodiments described above, but encompasses any and all embodiments within the scope of the following claims.

What is claimed is:

1. A method of forming a metallic interconnect structure, comprising steps of:
providing a semiconductor substrate on which a plurality of metallic interconnects are patterned;
forming a first metallic layer on the exposed surface of the substrate and the metallic interconnects;
performing etching back on the first metallic layer to expose the tops of the metallic interconnects and the surface of the substrate, wherein the remaining part of the first metallic layer on the sidewall of the metallic interconnects serves as a first metallic spacer;
forming a dielectric layer to cover the exposed surface of the substrate, the metallic interconnects and the first metallic spacer; and
performing a planarization technique on the dielectric layer.

2. The method according to claim 1, wherein the substrate comprises an anti-reflective coating (ARC) on the tops of the metallic interconnects.

3. The method according to claim 2, wherein the ARC is Ti/TiN or SiON.

4. The method according to claim 1, wherein the metallic interconnect is Al, Cu or Al—Si—Cu.

5. The method according to claim 1, wherein the first metallic layer is Ti, TiN, Ta, or TaN.

6. The method according to claim 1, wherein the dielectric layer is silicon dioxide.

7. The method according to claim 1, before forming the dielectric layer, further comprising steps of:
forming a second metallic layer on the exposed surface of the substrate, the metallic interconnects and the first metallic spacer; and
performing etching back on the second metallic layer to expose the tops of the metallic interconnects and the surface of the substrate, wherein the remaining part of the second metallic layer on the first metallic spacer serves as a second metallic spacer.

8. The method according to claim 7, wherein the first metallic layer is Ti, or Ta.

9. The method according to claim 7, wherein the second metallic layer is TiN, or TaN.

10. A metallic interconnect structure, comprising:
at least a metallic interconnect patterned on a semiconductor substrate; and
a first metallic spacer formed on the sidewall of the metallic interconnect.

11. The metallic interconnect structure according to claim 10, wherein the metallic interconnect is Al, Cu or Al—Si—Cu.

12. The metallic interconnect structure according to claim 10, wherein the first metallic layer is Ti, TiN, Ta, or TaN.

13. The metallic interconnect structure according to claim 10, wherein the substrate comprises an anti-reflective coating (ARC) on the tops of the metallic interconnects.

14. The metallic interconnect structure according to claim 13, wherein the ARC is Ti/TiN or SiON.

15. The metallic interconnect structure according to claim 10, further comprising a second metallic spacer formed on the first metallic spacer.

16. The metallic interconnect structure according to claim 15, wherein the first metallic layer is Ti, or Ta.

17. The metallic interconnect structure according to claim 15, wherein the second metallic layer is TiN, or TaN.
